(19) United States
(12) Patent Application Publication
(10) Pub. No.: US 2022/0310372 A1
(43) Pub. Date: Sep. 29, 2022

(54) PVD CHAMBER SHIELD STRUCTURE INCLUDING IMPROVED COTAING LAYER OR SHIELD

(71) Applicant: SK hynix Inc., Icheon (KR)

(72) Inventors: Gwang Sun JUNG, Icheon (KR); Jun Ku AHN, Icheon (KR); Young Ho LEE, Icheon (KR); Jong Ho LEE, Icheon (KR); Uk HWANG, Icheon (KR)

(21) Appl. No.: 17/474,831

(22) Filed: Sep. 14, 2021

(30) Foreign Application Priority Data
Mar. 25, 2021 (KR) 10-2021-0039025

(51) Int. Cl. H01J 37/34; C23C 14/34

(52) U.S. Cl. CPC H01J 37/3441; C23C 14/34; H01J 2237/332

(57) ABSTRACT

A PVD chamber shield includes: a shield configured to surround a space between a sputtering target and a substrate that are disposed in a PVD chamber body, the shield having a hollow shape with an inner surface and an outer surface; and a coating layer formed over the inner surface of the shield. The coating layer has i) a dielectric constant not greater than a dielectric constant of a material deposited over the substrate, ii) a porosity greater than 0 vol % and less than 100 vol %, and iii) a thickness greater than 150 pm and less than a given upper limit, the upper limit being set to prevent an occurrence of peeling of a material deposited over the coating layer.

### CROSS-REFERENCE TO RELATED APPLICATION

This patent document claims the priority and benefits of Korean Patent Application No. 10-2021-0039025, entitled “PVD CHAMBER SHIELD STRUCTURE INCLUDING IMPROVED COTAING LAYER OR SHIELD” and filed on Mar. 25, 2021, which is incorporated herein by reference in its entirety.

### TECHNICAL FIELD

Embodiments of the disclosed technology relate to a PVD (physical vapor deposition) chamber shield structure used in a PVD process.

### BACKGROUND

As electronic devices such as personal computers, mobile devices, or the like trend toward miniaturization, low power consumption, high performance, multi-functionality, memory devices capable of storing data in various electronic devices have been in demand. Thus, research has been conducted for developing memory devices having switching characteristics, i.e., devices capable of storing data by switching between different resistance states according to an applied voltage or current. Examples of memory devices include an RRAM (resistive random access memory), a PRAM (phase change random access memory), an FRAM (ferroelectric random access memory), an MRAM (magnetic random access memory), an E-fuse, and the like.

Various material layers included in such an electronic device, for example, a chalcogenide material layer may be usually formed by a physical vapor deposition, for example, by sputtering using a target formed of a chalcogenide material to be deposited in a PVD chamber. The PVD chamber may include a chamber body surrounding a space between a sputtering target and a substrate to be processed, and a shield structure for internal cleaning and protection for the structure in the chamber body.

### SUMMARY

The disclosed technology can be used in some implementations to provide a PVD chamber shield structure used in a PVD process.

In one aspect, a PVD chamber shield structure may include a shield configured to surround a space between a sputtering target and a substrate that are disposed in a PVD chamber body, the shield having a hollow shape with an inner surface and an outer surface; and a coating layer formed over the inner surface of the shield, wherein the coating layer may have a dielectric constant not greater than that of a material deposited over the substrate during a PVD process.

In another aspect, a PVD chamber shield structure may include a shield configured to surround a space between a sputtering target and a substrate that are disposed in a PVD chamber body, the shield having a hollow shape with an inner surface and an outer surface; and a coating layer formed over the inner surface of the shield, wherein the coating layer may have a porosity greater than 0 vol % and less than 100 vol %.

In another aspect, a PVD chamber shield structure may include a shield configured to surround a space between a sputtering target and a substrate that are disposed in a PVD chamber body, the shield having a hollow shape with an inner surface and an outer surface; and a coating layer formed over the inner surface of the shield, wherein the coating layer may have a thickness greater than 150 μm and less than a given upper limit, the upper limit being set to prevent an occurrence of peeling of a material deposited over the coating layer.

In another aspect, a PVD chamber shield structure may include a shield configured to surround a space between a sputtering target and a substrate that are disposed in a PVD chamber body, the shield having a hollow shape with an inner surface and an outer surface, wherein a material deposited over the substrate during a PVD process may be deposited over the inner surface of the shield, and wherein the shield may have a dielectric constant not greater than that of the material deposited over the substrate.

In still another aspect, a PVD chamber shield structure may include a shield configured to surround a space between a sputtering target and a substrate that are disposed in a PVD chamber body, the shield having a hollow shape with an inner surface and an outer surface, wherein a material deposited over the substrate during a PVD process may be deposited over the inner surface of the shield, and wherein the shield may have a porosity greater than 0 vol % and less than 100 vol %.

In still another aspect, a PVD chamber shield structure may include a shield configured to surround a space between a sputtering target and a substrate that are disposed in a PVD chamber body, the shield having a hollow shape with an inner surface and an outer surface, wherein a material deposited over the substrate during a PVD process may be deposited over the inner surface of the shield, and wherein the shield may have a thickness greater than 150 μm and less than a given upper limit, the upper limit being set to prevent an occurrence of peeling of the material deposited over the shield.

These and other aspects, implementations and associated beneficial aspects are described in greater detail in the drawings, the description, and the claims.

### BRIEF DESCRIPTION OF THE DRAWINGS

FIGS. 1A and 1B illustrate a PVD chamber shield structure according to an implementation of the disclosed technology. FIGS. 1C and 1D illustrate a PVD chamber shield structure according to an implementation of the disclosed technology.

FIG. 2 is a graph showing the relationship between a burn-in time and the reciprocal of the capacitance.

FIG. 3 is a perspective view illustrating a semiconductor memory according to an implementation of the disclosed technology.

FIGS. 4A, 4B, 4C, and 4D are cross-sectional views illustrating a semiconductor memory and a method for fabricating the semiconductor memory according to an implementation of the disclosed technology.

### DETAILED DESCRIPTION

Various examples and implementations of the disclosed technology are described below in detail with reference to the accompanying drawings.

The drawings may not be necessarily to scale and in some instances, proportions of at least some of substrates in the drawings may have been exaggerated to illustrate certain features of the described examples or implementations. In presenting a specific example in a drawing or description having two or more layers in a multi-layer substrate, the relative positioning relationship of such layers or the sequence of arranging the layers as shown reflects a particular implementation for the described or illustrated example and a different relative positioning relationship or sequence of arranging the layers may be possible.

Various material layers included in such an electronic device, for example, a chalcogenide material layer may be usually formed by a physical vapor deposition. For example, such a material layer may be formed by sputtering using a target formed of a chalcogenide material to be deposited in a PVD chamber.

The PVD chamber may include a chamber body surrounding a space between a sputtering target and a substrate to be processed, and a shield structure for internal cleaning and protection for components in the chamber body. The shield structure disposed in the chamber body includes a shield with a hollow shape having an inner surface and an outer surface. The shield structure may optionally further include a coating layer formed over the inner surface.

When performing a PVD process for the material layer such as the chalcogenide material layer by using the PVD chamber, it is desirable to stabilize a capacitance inside the chamber by performing a burn-in process in order to ensure process stabilization after performing new equipment setup or preventive maintenance process. Accordingly, a method capable of effectively decreasing a burn-in time may be desirable in terms of process efficiency.

In implementations of the disclosed technology, one or more of a dielectric constant, a porosity, and a thickness of a coating layer or a shield of a PVD chamber shield structure can be adjusted to an optimal range, thereby decreasing a capacitance of the coating layer or the shield. As a result, a total capacitance inside the chamber can be decreased so as to effectively reduce a burn-in time for stabilizing the capacitance in the chamber.

Hereinafter, a PVD chamber shield structure in accordance with implementations of the disclosed technology will be described. First, implementations where the capacitance of the coating layer and the total capacitance in the chamber can be decreased by controlling the coating layer of the PVD chamber shield structure will be explained, and then, implementations where the capacitance of the shield and the total capacitance in the chamber can be decreased by controlling the shield of the PVD chamber shield structure will be explained.

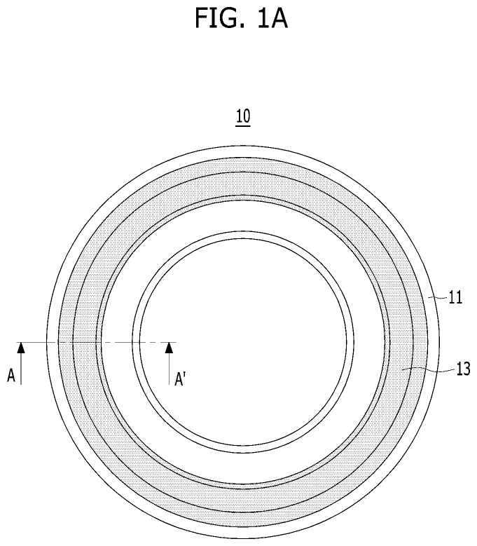

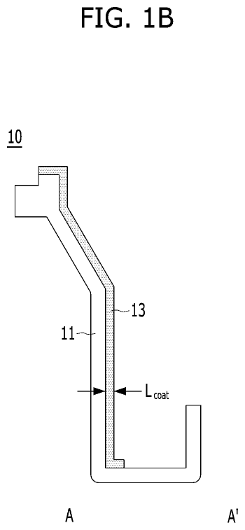

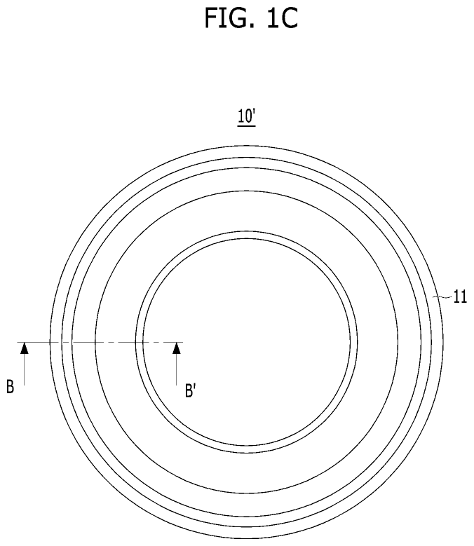

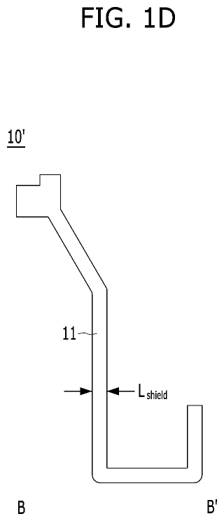

FIGS. 1A and 1B are schematic diagrams of a PVD chamber shield structure 10 according to an implementation of the disclosed technology. FIG. 1A is a schematic top view and FIG. 1B is a schematic cross-sectional view along the line A-A′ shown in FIG. 1A.

The PVD chamber shield structure 10 in FIGS. 1A and 1B may be applied to the deposition equipment which is known and used in the art. Therefore, some known aspects for the PVD chamber shield structure 10 may be omitted herein for the interest of brevity, and description will be focused on features of the disclosed technology such as a shield 11 and a coating layer 13.

The PVD chamber shield structure 10 may be disposed to surround a space between a sputtering target and a substrate to be processed in a PVD chamber body which is electrically grounded. The PVD chamber shield structure 10 may serve to clean and protect components in the PVD chamber body. That is, for the maintenance and utilization of the chamber, the PVD chamber shield structure 10 may be disposed in the chamber body to substantially prevent deposition of sputtered material on the chamber walls and other chamber components and substantially prevent the chamber body and other chamber components from being significantly damaged or contaminated during the PVD process.

The PVD chamber shield structure 10 may include the shield 11 and the coating layer 13.

The shield 11 may be deposited to surround a space between a sputtering target and a substrate to be processed. The shield 11 may have a hollow shape with an inner surface and an outer surface.

In an implementation of the disclosed technology, the shield 11 may have a hollow cylindrical shape which is symmetrical about a central axis. Alternatively, the shield 11 may have a hollow cylindrical shape which is symmetrical about a central axis and has a diameter that increases from a lower part to an upper part in the central axis direction. However, the shape of the shield 11 is not limited to that shown in the implementation of FIGS. 1A and 1B and may have various shapes according to implementations.

In an implementation of the disclosed technology, the shield 11 may be formed of a material having resistance to corrosion caused by a gas generated during the PVD process.

In an implementation of the disclosed technology, the shield 11 may include a metal. For example, the shield 11 may include one or more of aluminum, titanium, tantalum, stainless steel, copper, and chrome.

In another implementation of the disclosed technology, the shield 11 may include a ceramic material. For example, the shield 11 may include one or more of alumina, silica, zirconia, a silicon nitride, and an aluminum nitride.

The shield 11 may be formed of one component, or may be a one-piece structure formed of two or more components that are welded. Since, when the shield 11 is formed of a plurality of pieces, it may cause peeling of the deposited materials, it is preferably formed as a one-piece structure.

The coating layer 13 may be formed at a predetermined thickness L_{coat} over a part of the inner surface of the shield 11 or substantially the entire inner surface of the shield 11. In an implementation of the disclosed technology, the coating layer 13 may not be formed over the outer surface of the shield 11. However, in some implementations of the disclosed technology, the coating layer 13 may be formed over a part of the outer surface of the shield 11 or substantially the entire outer surface of the shield 11. In other implementations of the disclosed technology, the coating layer 13 may be formed substantially the entire exposed surfaces of the chamber shield structure 10.

During the PVD process, a material may be deposited over the coating layer 13. The material may be a material to be deposited over the substrate by the PVD process. In an implementation of the disclosed technology, the material may be an ovonic threshold switching (OTS) material including a chalcogenide material. The OTS material may be used as a selection element layer in a cross-point semiconductor array structure. However, the material to be deposited is not limited to the OTS material. In another implementation of the disclosed technology, the material to be deposited may be any material included in a semiconductor device.

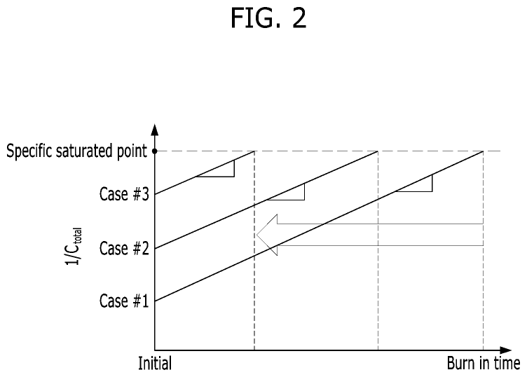

Depending on a total capacitance in the chamber, a burn-in time for stabilization of the capacitance in the chamber may vary. This will be described in detail with reference to FIG. 2.

FIG. 2 is a graph showing the relationship between the burn-in time and the reciprocal of the capacitance (e.g., the total capacitance in the chamber) according to implementations of the present disclosure.

A burn-in process may be performed to stabilize the capacitance in the PVD chamber for process stabilization after performing new equipment setup or preventive maintenance process. The burn-in time represents the time required for the burn-in process. Since the burn-in time may be excessively long, it is desirable to reduce the burn-in time required to reach a critical point in view of a process efficiency.

In the implementation of the disclosed technology, a value of 1/Cₜₒₜₐₗ may be expressed as Equation 1 or 2.

$$\frac{1}{{C}_{total}} = ( \frac{1}{{C}_{vac}} ) + ( \frac{1}{{C}_{deposit}} ) + ( \frac{1}{{C}_{coat}} ) \qquad [ Equation 1 ]$$

$$\frac{1}{{C}_{total}} = ( \frac{1}{{C}_{vac}} ) + ( \frac{1}{{C}_{deposit}} ) + ( \frac{1}{{C}_{coat}} ) \qquad [ Equation 2 ]$$

In the above Equation 1 and 2, Cₜₒₜₐₗ represents the total capacitance in the PVD chamber, C_{vac} represents a capacitance of an empty space between a sputtering target to which power is applied and the structure 10, C_{deposit} represents a capacitance of a material to be deposited over the coating layer 13, C_{coat} represents a capacitance of the coating layer 13, and C_{shield} represents a capacitance of the shield 11.

When the shield 11 is formed of a metal, the chamber body is formed of a metal. Therefore, no capacitance is formed between the shield 11 and the chamber body. In this case, the reciprocal of the total capacitance may be expressed as Equation 1.

When the shield 11 is formed of a ceramic, the reciprocal of the total capacitance may be expressed as Equation 2.

The reciprocal of the capacitance of the coating layer 13 may be expressed as Equation 3.

$$\frac{1}{{C}_{coat}} = \frac{1}{{ε}_{coat}} \times \frac{1}{{A}_{coat}} \times {L}_{coat} \qquad [ Equation 3 ]$$

In the above Equation 3, C_{coat} represents the capacitance of the coating layer 13, ε_{coat} represents a permittivity of the coating layer 13, A_{coat} represents an area of the coating layer 13, and L_{coat} represents a thickness of the coating layer 13.

In an implementation of the disclosed technology, the material to be deposited over the substrate, i.e., the material to be deposited over the coating layer 13 of the PVD shield structure 10 may include an ovonic threshold switching (OTS) material including a chalcogenide material. However, the material to be deposited is not limited to the OTS material. In another implementation of the disclosed technology, the material to be deposited may be any material included in a semiconductor device.

For convenience of explanation, in the present specification, the OTS material will be exemplified as the material to be deposited over the substrate, i.e., the material to be deposited over the coating layer 13 during the PVD process. However, the OTS material is only an example of the material deposited over the substrate, and the material to be deposited over the substrate is not limited thereto.

In FIG. 2, a specific saturated point (i.e., a critical point) may represent a 1/Cₜₒₜₐₗ value in case that a thickness non-uniformity is stabilized.

The thickness non-uniformity may refer to the distribution of a thickness of the material to be deposited over the substrate during the PVD process, for example, the OTS film. A small thickness non-uniformity may indicate that the deposited OTS film has a substantially uniform thickness. As the PVD process progresses, the thickness of the deposited OTS film tends to be non-uniform at first and then gradually become uniform. That is, the thickness non-uniformity is high at the beginning of the process, but tends to gradually decrease as the process progresses.

During the PVD process, the capacitance of the OTS material C_{deposit} may significantly change according to the accumulated thickness of the OTS material deposited over the coating layer 13. Due to the change in the capacitance of the OTS material C_{deposit}, a plasma distribution on the sputtering target may change so that the sputtering may be non-uniformly performed, thereby affecting the thickness non-uniformity.

As shown in FIG. 2, in each of Case #1, Case #2, and Case #3, the burn-in time for which the 1/Cₜₒₜₐₗ value reaches the saturated point may vary. The burn-in time for reaching the saturated point is reduced in the order of Case#1, Case #2, and Case #3. For example, the reciprocal 1/Cₜₒₜₐₗ of the total capacitance may be increased with a specific slope (e.g., 1/(ε_{deposit}*A_{deposit}) where ε_{deposit} denotes a permittivity of the material to be deposited over the coating layer 13 and A_{deposit} denotes an area of the deposited material) in each of Case #1, Case #2, and Case #3. Since values of the reciprocal 1/Cₜₒₜₐₗ of the total capacitance in Case #1, Case #2, and Case #3 at an initial time Initial are increased in the order of Case #1, Case #2, and Case #3, a time interval (e.g., the burn-in time) to reach from these initial values to the specific saturated point may be reduced in the order of Case #1, Case #2, and Case #3. Therefore, in order to decrease the burn-in time for reaching the saturated point, it is necessary to increase the 1/Cₜₒₜₐₗ value, that is, decrease the total capacitance Cₜₒₜₐₗ. For example, the initial values of the reciprocal 1/Cₜₒₜₐₗ of the total capacitance at the initial time Initial may be increased by adjusting the capacitance C_{coat} of the coating layer 13, thereby reducing the burn-in time.

In implementations of the disclosed technology, a material included in the coating layer 13 and a thickness of the coating layer 13 may be optimized so that the 1/Cₜₒₜₐₗ value can quickly reach the saturated point.

In implementations of the disclosed technology, the capacitance C_{coat} of the coating layer 13 can be effectively reduced in consideration of three aspects, that is, i) the dielectric constant ε_{r_coat} of the coating layer 13; ii) the porosity of the coating layer 13; and iii) the thickness L_{coat} of the coating layer 13.

In the first aspect, the coating layer 13 may be formed of a material having the dielectric constant ε_{r_coat} to effectively reduce the capacitance C_{coat} of the coating layer 13.

To this end, the dielectric constant of the coating layer ε_{r_coat} 13 may have a value greater than a dielectric constant ε_{r_vac} of vacuum and not greater than the dielectric constant ε_{r_deposit} of the material deposited over the coating layer 13. That is, it is desirable that the coating layer 13 has a low dielectric constant εr__{coat} within a range less than the dielectric constant ε_{r_deposit} in order to reduce the capacitance C_{coat} of the coating layer 13. Therefore, the dielectric constant εr__{coat} may be suitably selected within the range (ε_{r_vac}<ε_{r_coat}<ε_{r_deposit}) in view of reducing the capacitance C_{coat} and thus the capacitance Cₜₒₜₐₗ along with considering process conditions. In implementation of the disclosed technology, when depositing the OTS material, the upper limit of ε_{r_coat} may be the dielectric constant ε_{r_deposit} of the deposited OTS material. However, in another implementation of the disclosed technology, when depositing a material other than the OTS material, the upper limit of ε_{r_coat} may be a dielectric constant of the deposited material.

In an implementation, the dielectric constant ε_{r_coat} of the coating layer 13 may satisfy the relationship of ε_{r_vac}<ε_{r_coat}≤ε_{r_deposit}.

In another implementation, the dielectric constant ε_{r_coat} of the coating layer 13 may satisfy the relationship of ε_{r_vac}<ε_{r_coat}<ε_{r_deposit}.

In another implementation, when depositing the OTS material, since a dielectric constant of the common OTS material is about 7, the dielectric constant ε_{r_coat} of the coating layer 13 may satisfy the relationship of 1<ε_{r_coat}<7.

In another implementation, the coating layer 13 may include one or more OTS materials including a chalcogenide material such as GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds and YSZ (Yttria-stabilized Zirconia). Here, each of the terms “Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds” may refer to a compound including indicated elements.

In accordance with the first aspect, when the coating layer 13 has the dielectric constant ε_{r_coat} greater than ε_{r_vac} and not greater than ε_{r_deposit}, it is possible to reduce the capacitance of the coating layer 13 and thus the total capacitance in the chamber, and shorten the burn-in time for reaching the total capacitance at a time point when the thickness non-uniformity is stabilized, compared with the case where the coating layer 13 includes a metal or a ceramic. For example, the coating layer 13 has the dielectric constant ε_{r_coat} that is less than a dielectric constant of a ceramic material, and thus the capacitance of the coating layer 13 may be reduced compared to that when the coating layer 13 includes the ceramic material. As a result, the total capacitance in the chamber may be reduced compared to that when the coating layer 13 includes the ceramic material.

In case of increasing the porosity or the thickness of the coating layer 13 in accordance with the second and third aspects described in detail below, a material having a dielectric constant greater than the range mentioned in the first aspect may be used as the coating layer 13. That is, when the method according to the second and/or third aspect is used, it is possible to have a wide range of choice for the material of the coating layer 13.

In the second aspect, the porosity of the coating layer 13 can be useful to reduce the capacitance C_{coat} of the coating layer 13.

A dielectric constant of a porous material may be expressed as Equation 4:

ε_{r_mixture}=x*ε_{r_vac′}+(1−x)*ε_{r_coat}. [Equation 4]

In the above Equation 4, x represents a ratio of vacuum or air included in the pores of the porous material (where a fraction corresponding to 100 vol % is expressed as 1) and 0<x<1. For example, x represents a volume fraction (or a porosity) that is a ratio of a volume of the pores over a total volume of the porous material. ε_{r_vac′} represents a dielectric constant of vacuum or air, and ε_{r_mixture} represents a dielectric constant of a porous material included in the coating layer 13.

As the porosity of the coating layer 13 is increased, the dielectric constant of the coating layer 13 can be decreased, and thus the capacitance C_{coat} of the coating layer 13 can be lowered. The porosity of the coating layer 13 can be controlled within a range greater than 0 vol % and less than 100 vol %. For example, the porosity of the coating layer 13 may be not greater than 22 vol %. Preferably, the porosity of the coating layer 13 may be a range from 3 vol % to 22 vol %, more preferably from 0.03 vol % to 10 vol %. When the porosity of the coating layer 13 is less than 3 vol %, it may be difficult to sufficiently exhibit the effect of reducing the capacitance C_{coat} of the coating layer 13. When the porosity of the coating layer 13 is greater than 22 vol %, a hardness of the coating layer 13 may be lowered, thereby causing a damage to the coating layer 13 and generating particles, and adhesion properties (e.g., adhesion force) between the coating layer 13 and a material to be deposited over the coating layer 13 may deteriorated.

In accordance with this aspect, even when the coating layer 13 is formed of a conventional material, the dielectric constant of the coating layer 13 can be effectively lowered by controlling the porosity of the coating layer 13, and thus the capacitance C_{coat} of the coating layer 13 can be decreased. Therefore, it is possible to have a wide range of choice for the material of the coating layer 13.

In accordance with the second aspect, when the coating layer 13 is formed of the material having the porosity, it is possible to reduce the capacitance of the coating layer 13 and thus the total capacitance in the chamber, and shorten the burn-in time for reaching the total capacitance at a time point when the thickness non-uniformity is stabilized, compared with the case where the coating layer 13 includes the same material having no porosity.

In an implementation, the coating layer 13 may include one or more of OTS materials including a chalcogenide material such as GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds and YSZ (Yttria-stabilized Zirconia).

In the third aspect, the thickness of the coating layer 13 L_{coat} can be useful to reduce the capacitance C_{coat} of the coating layer 13.

As shown in Equation 3, the capacitance C_{coat} of the coating layer 13 may be decreased as the thickness L_{coat} of the coating layer 13 is increased. Therefore, in this aspect, the capacitance C_{coat} of the coating layer 13 can be lowered by increasing the thickness L_{coat} of the coating layer 13, and thus the burn-in time for reaching the critical point can be reduced.

In an implementation, the coating layer 13 may be formed to be thicker than the conventional coating thickness (e.g., 50-150 μm). The upper limit of the thickness may be a range where peeling of the material deposited over the coating layer 13 does not occur.

For example, the thickness L_{coat} of the coating layer 13 L_{coat} may satisfy the relationship of 150 μm<L_{coat}<1 mm.

In accordance with this aspect, even when the coating layer 13 is formed of a conventional material, the capacitance C_{coat} of the coating layer 13 can be decreased by increasing the thickness of the layer 13. Therefore, it is possible to have a wide range of choice for the material of the coating layer 13.

In accordance with the third aspect, when the coating layer 13 has the thickness in a range greater than 150 μm and less than a given upper limit, the upper limit being set to prevent an occurrence of peeling of the material deposited over the coating layer 13, preferably in a range of 150 μm<L_{coat}<1 mm, it is possible to reduce the capacitance of the coating layer 13 and thus the total capacitance in the chamber, and shorten the burn-in time for reaching the total capacitance at a time point when the thickness non-uniformity is stabilized, compared with the case where the thickness of the coating layer 13 is not more than 150 μm.

In an implementation, the coating layer 13 may include one or more OTS materials including a chalcogenide material such as GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds and YSZ (Yttria-stabilized Zirconia).

As such, in implementations of the disclosed technology, the capacitance C_{coat} of the coating layer 13 can be effectively reduced by adjusting one or more of the dielectric constant, the porosity, and the thickness of the coating layer 13. As a result, it is possible to effectively decrease the burn-in time for reaching the critical point which corresponds to the 1/Cₜₒₜₐₗ value at a time point when the thickness non-uniformity of the deposited material is stabilized.

In the above implementations, the PVD chamber shield structure 10 includes the coating layer 13. The capacitance C_{coat} of the coating layer 13 and thus, the total capacitance Cₜₒₜₐₗ can be effectively reduced by adjusting one or more of the dielectric constant, the porosity, and the thickness of the coating layer 13.

However, in another implementation, the shield structure 10 does not include the coating layer 13. In such implementations, the capacitance C_{shield} of the shield 11 and thus, the total capacitance Cₜₒₜₐₗ can be decreased by controlling one or more of a dielectric constant, a porosity, and a thickness of the shield 11. This implementation will be described below with reference to FIGS. 1C and 1D and some of repetitive description of the similar parts to those described in the above implementations may be omitted for the interest of brevity.

FIGS. 1C and 1D are schematic diagrams of a PVD chamber shield structure 10′ according to an implementation of the disclosed technology. FIG. 1C is a schematic top view and FIG. 1D is a schematic cross-sectional view along the line B-B′ shown in FIG. 1C.

Compared to the shield structure 10 shown in FIGS. 1A and 1B, the shield structure 10′ in FIGS. 1C and 1D does not include the coating layer 13. In the shield structure 10′, one or more of the dielectric constant, the porosity, and the thickness of the shield 11 may be controlled in substantially the same way as applied to the coating layer 13 of the above implementations.

In the implementations, a value of 1/Cₜₒₜₐₗ may be expressed as Equation 5.

$$\frac{1}{{C}_{total}} = ( \frac{1}{{C}_{vac}} ) + ( \frac{1}{{C}_{deposit}} ) + ( \frac{1}{{C}_{shield}} ) \qquad [ Equation 5 ]$$

In the above Equation 5, Cₜₒₜₐₗ represents the total capacitance in the PVD chamber, C_{vac} represents the capacitance of an empty space between a sputtering target to which power is applied and the structure 10′, C_{deposit} represents the capacitance of a material to be deposited over an inner surface of the shield 11, and C_{shield} represents the capacitance of the shield 11.

The reciprocal of the capacitance C_{shield} of the shield 11 may be expressed as Equation 6.

$$( \frac{1}{{C}_{shield}} ) = \frac{1}{{ε}_{shield}} \times \frac{1}{{A}_{shield}} \times {L}_{shield} \qquad [ Equation 6 ]$$

In the above Equation 6, C_{shield} represents the capacitance of the shield 11, ε_{shield} represents a permittivity of the shield 11, A_{shield} represents an area of the shield 11, and L_{shield} represents a thickness of the shield 11.

In implementations, a material included in the shield 11 and the thickness L_{shield} of the shield 11 may be optimized so that the 1/Cₜₒₜₐₗ value can quickly reach the saturated point. That is, the technology for controlling the coating layer 13 of the shield structure 10 in the above implementation can be applied to control the shield 11 of the shield structure 10′ in the implementations.

In implementations of the disclosed technology, the capacitance C_{shield} of the shield 11 can be effectively reduced in consideration of three aspects, that is, i) the dielectric constant ε_{r_shield} of the shield 11; ii) the porosity of the shield 11; and iii) the thickness L_{shield} of the shield 11.

In the first aspect, the shield 11 may be formed of a material having the dielectric constant ε_{r_shield} to effectively reduce the capacitance C_{shield} of the shield 11. In an implementation of the disclosed technology, the dielectric constant ε_{r_shield} of the shield 11 may have a value greater than a dielectric constant ε_{r_vac} of vacuum and not more than the dielectric constant of the material ε_{r_deposit} deposited over the inner surface of the shield 11. That is, it is desirable that the shield 11 has a low dielectric constant ε_{r_shield} within a range less than the dielectric constant ε_{r_deposit} in order to reduce the capacitance C_{shield} of the shield 11. Therefore, the dielectric constant ε_{r_shield} may be suitably selected within the range (ε_{r_vac}<ε_{r_shield}<ε_{r_deposit}) in view of reducing the capacitance C_{shield} of the shield 11 and thus the capacitance Cₜₒₜₐₗ along with considering process conditions.

In the second aspect, the porosity of the shield 11 can be useful to reduce the capacitance C_{shield} of the shield 11. As the porosity of the shield 11 is increased, the dielectric constant of the shield 11 can be decreased, and thus the capacitance C_{shield} of the shield 11 can be lowered. The porosity of the shield 11 can be controlled within a range greater than 0 vol % and less than 100 vol %. For example, the porosity of the shield 11 may be not greater than 22 vol %. Preferably, the porosity of the shield 11 may be a range from 3 vol % to 22 vol %, more preferably from 0.03 vol % to 10 vol %. When the porosity of the shield 11 is less than 3 vol %, it may be difficult to sufficiently exhibit the effect of reducing the capacitance C_{shield} of the shield 11. When the porosity of the shield 11 is greater than 22 vol %, a hardness of the shield 11 may be lowered, thereby causing a damage to the shield 11 and generating particles, and adhesion properties (e.g., adhesion force) between the shield 11 and a material to be deposited over the shield 11 may deteriorated.

In the third aspect, the thickness L_{shield} of the shield 11 can be useful to reduce the capacitance C_{shield} of the shield 11. As shown in Equation 6, the capacitance C_{shield} of the shield 11 C_{shield} may be decreased as the thickness L_{shield} of the shield 11 is increased. Therefore, in this aspect, the capacitance C_{shield} of the shield 11 can be lowered by increasing the thickness L_{shield} of the shield 11, and thus the burn-in time for reaching the critical point can be reduced. The shield 11 may be formed to be thicker than the conventional shield thickness (e.g., 50-150 μm). The upper limit of the thickness of the shield 11 may be a range where peeling of the material deposited over the shield 11 does not occur. For example, the thickness L_{shield} of the shield 11 may satisfy the relationship of 150 μm<L_{shield}<1 mm.

As such, in implementations of the disclosed technology, the capacitance C_{shield} of the shield 11 can be effectively reduced by adjusting one or more of the dielectric constant, the porosity, and the thickness of the shield 11. As a result, it is possible to effectively decrease the burn-in time for reaching the critical point which corresponds to the 1/Cₜₒₜₐₗ value at a time point when the thickness non-uniformity of the deposited material is stabilized.

Hereinafter, an electronic device including a selection element layer formed by a PVD process using the PVD chamber shield structure in accordance with the above-described implementations will be described.

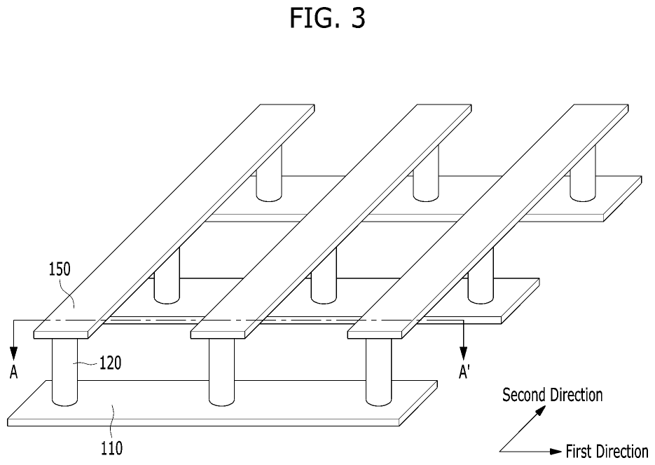

FIG. 3 is a perspective view of a semiconductor memory in accordance with an implementation of the disclosed technology.

The semiconductor memory may have a cross-point structure which includes first lines 110 each extending in a first direction, second lines 150 located over the first lines 110 and each extending in a second direction crossing the first direction, and memory cells 120 located between the first lines 110 and the second lines 150. The memory cells 120 are disposed at respective intersections of the first lines 110 and the second lines 150.

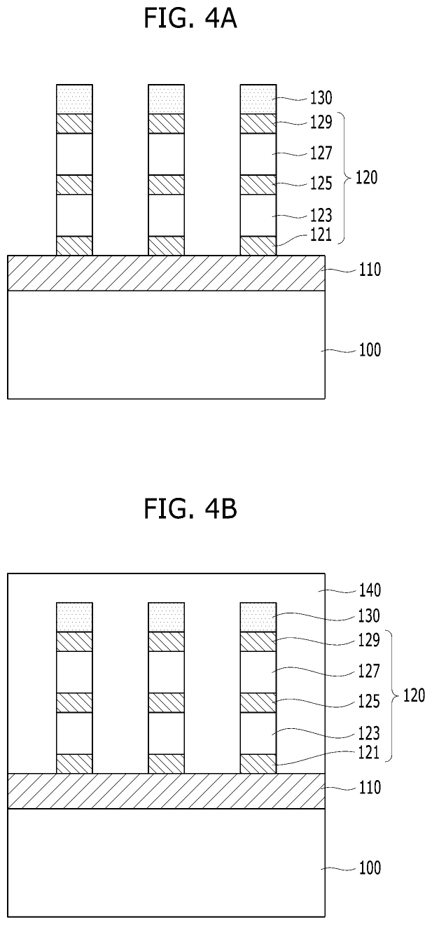

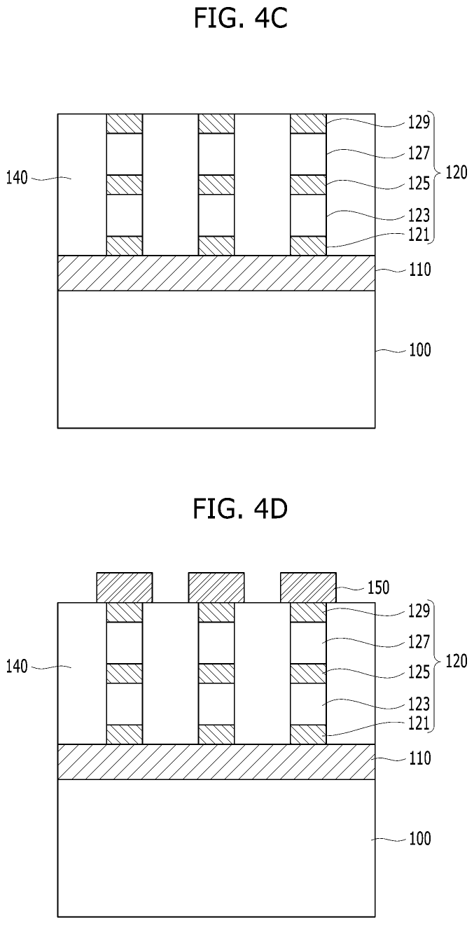

FIGS. 4A to 4D are cross-sectional views illustrating a semiconductor memory and a method for fabricating the semiconductor memory in accordance with an implementation of the disclosed technology.

For example, FIG. 4D is a cross-sectional view of the semiconductor device taken along line A-A′ of FIG. 3.

Referring to FIG. 4A, a substrate 100 including given structures (not shown) may be provided. For example, the given structures may include one or more transistors for controlling the first lines 110, the second lines 150, or the first and second lines 110 and 150 of FIGS. 3 and 4D, which are formed over the substrate 100.

Then, the first lines 110 each extending in a first direction (e.g., a horizontal direction in FIG. 4A) may be formed over the substrate 100. The first lines 110 may have a single-layered structure or a multi-layered structure, and may include a conductive material such as a metal, a metal nitride, or the like. The first lines 110 may be formed by depositing the conductive material and patterning a deposited conductive material layer. Spaces between the first lines 110 may be filled with an insulating material (not shown).

Then, a plurality of memory cells 120 may be formed over the first lines 110. In the implementation shown in FIG. 4A, each of the plurality of memory cells 120 may have a pillar shape. The plurality of memory cells 120 may be arranged in a matrix having rows and columns. The rows each extend along the first direction and the columns each extend along a second direction crossing the first direction. The memory cells 120 may be disposed in respective intersection regions of the first lines 110 and the second lines 150. For example, the intersection region is a three-dimensional region where the first line 110 and the second line 150 overlap each other when viewed in a plan view. In an implementation, each of the memory cells 120 may have a size that is substantially equal to or smaller than that of the intersection region. In another implementation, each of the memory cells 120 may have a size that is larger than that of the intersection region.

The memory cells 120 may be formed by depositing a plurality of material layers (not shown) over a structure including the first lines 110 and the insulating material (not shown), forming a plurality of hard mask patterns 130 over the plurality of material layers, and etching the material layers using the hard mask patterns 130 as an etching barrier. Therefore, each of the hard mask patterns 130 has sidewalls substantially aligned with sidewalls of a corresponding one of the memory cells 120.

The hard mask patterns 130 may function as an etching barrier while etching the material layers for forming the memory cells 120 and include one or more of various materials having etch selectivity with respect to the memory cells 120. For example, each of the hard mask patterns 130 may have a single-layered structure or a multi-layered structure and include an insulating material such as a silicon oxide, a silicon nitride, a silicon oxynitride, or the like.

Also, in this implementation of FIG. 4A, each of the plurality of memory cells 120 may include a lower electrode layer 121, a selection element layer 123, a middle electrode layer 125, a variable resistance layer 127, and an upper electrode layer 129, which are sequentially stacked over a corresponding first line 110.

Specifically, the lower electrode layer 121 may be located at a lowermost portion of the memory cell 120 and function as a transmission path of a voltage or a current between a corresponding one of the first lines 110 and the remaining portion (e.g., the element layers 123, 125, 127, and 129). The middle electrode layer 125 may physically separate the selection element layer 123 from the variable resistance layer 127, and electrically couple the selection element layer 123 to the variable resistance layer 127. For example, a current flow through the selection element layer 123, the middle electrode layer 125, and the variable resistance layer 127 when a voltage level of a voltage applied across the selection element layer 123 is equal to or greater than a given threshold voltage level.

The upper electrode layer 129 may be located at an uppermost portion of the memory cell 120 and function as a transmission path of a voltage or a current between a corresponding one of the second lines 150 of FIG. 2D and the remaining portion (e.g., the element layers 121, 123, 125, and 127). Each of the lower electrode layer 121, the middle electrode layer 125, and the upper electrode layer 129 may have a single-layered structure or a multi-layered structure and include a conductive material such as a metal, a metal nitride, a conductive carbon material, or the like.

The selection element layer 123 may control access to the variable resistance layer 127. That is, the selection element layer 123 may function as a switching element and have a selection element characteristic for substantially preventing a current from passing through the selection element layer 123 when a magnitude of an applied voltage or an applied current is lower than a critical value (or a threshold value) and causing a current to pass through the selection element layer 123 when the magnitude of the applied voltage or the applied current is substantially equal to or greater than the critical value. For example, a magnitude of the current passing through the selection element layer 123 is proportional to the magnitude of the voltage or current applied to the selection element layer 123.

In some implementations, the selection element layer 123 may include an MIT (metal insulator transition) element such as NbO₂ or TiO₂; an MIEC (mixed ion-electron conducting) element such as ZrO₂ (Y₂O₃), Bi₂O₃—BaO, or (La₂O₃)ₓ(CeO₂)₁₋ₓ; an OTS (ovonic threshold switching) element including a chalcogenide-based material, such as Ge₂Sb₂Te₅, As₂Te₃, As₂, or As₂Se₃; a tunneling insulation layer including an insulation material such as a silicon oxide, a silicon nitride, or a metal oxide and allowing tunneling of electrons; or a combination thereof. The selection element layer 123 may have a single-layered structure or a multi-layered structure exhibiting the selection element characteristic with a combination of two or more layers.

In an implementation, the selection element layer 123 may include a material such as a chalcogenide material which is formed by a PVD process in a chamber using the shield structure 10 of FIGS. 1A and 1B or the shield structure 10′ of FIGS. 1C and 1D in accordance with the above-described implementations.

In an implementation of the disclosed technology, the selection element layer 123 may include an OTS material including a chalcogenide material which is formed by the PVD process in the chamber using the shield structure 10 including the shield 11 and the coating layer 13 shown in FIGS. 1A and 1B. The coating layer 13 of the shield structure 10 may satisfy one or more of the conditions as below:

i) The coating layer 13 has a dielectric constant the dielectric constant which is greater than a dielectric constant ε_{r_vac} of vacuum and not more than the dielectric constant ε_{r_deposit} of the material deposited over the coating layer 13.

ii) The coating layer 13 has a porosity in a range greater than 0 vol % and less than 100 vol %, preferably of 0.03 vol % to 22 vol %.

iii) The thickness of the coating layer 13 is in a range greater than 150 μm and less than a given upper limit, the upper limit being set to prevent an occurrence of peeling of the material deposited over the coating layer 13.

In accordance with the PVD chamber shield structure 10, the capacitance of the coating layer 13 and thus the total capacitance in the chamber can be decreased. Therefore, it is possible to reduce the burn-in time for reaching 1/Cₜₒₜₐₗ at a time point when the thickness non-uniformity is stabilized and improve process efficiency.

In another implementation of the disclosed technology, the selection element layer 123 may include an OTS material including a chalcogenide material which is formed by the PVD process in the chamber using the shield structure 10′ including the shield 11 shown in FIGS. 1C and 1D. The shield structure 10′ may satisfy one or more of the conditions as below:

i) The shield 11 has a dielectric constant the dielectric constant which is greater than a dielectric constant ε_{r_vac} of vacuum and not more than the dielectric constant ε_{r_deposit} of the material deposited over the inner surface of the shield 11.

ii) The shield 11 has a porosity in a range greater than 0 vol % and less than 100 vol %, preferably of 0.03 vol % to 22 vol %.

iii) The thickness of the shield 11 is in a range greater than 150 μm and less than a given upper limit, the upper limit being set to prevent an occurrence of peeling of the material deposited over the shield 11.

In accordance with the PVD chamber shield structure 10′, the capacitance of the shield 11 and thus the total capacitance in the chamber can be decreased. Therefore, it is possible to reduce the burn-in time for reaching 1/Cₜₒₜₐₗ at a time point when the thickness non-uniformity is stabilized and improve process efficiency.

Since the shield structures 10 and 10′ have been described in detail in the above-mentioned implementations, detailed description thereof may be omitted in this implementation to avoid repetition.

The variable resistance layer 127 may switch between different resistance states according to a voltage or a current applied to the variable resistance layer 127 through the upper electrode layer 129 and the middle electrode layer 125, thereby storing data having one of different logic values corresponding to the different resistance states. For example, when the variable resistance layer 127 is in a low resistance state, data having a first logic value of ‘1’ may be stored in the variable resistance layer 127. On the other hand, when the variable resistance layer 127 is in a high resistance state, data having a second logic value of ‘0’ may be stored in the variable resistance layer 127.

The variable resistance layer 127 may include one or more of various materials that are used in RRAM, PRAM, FRAM, MRAM, and the like. For example, the variable resistance layer 127 may include one or more of a metal oxide such as a transition metal oxide or a perovskite-based material, a phase-change material such as a chalcogenide-based material, a ferroelectric material, a ferromagnetic material, and the like. The variable resistance layer 127 may have a single-layered structure or a multi-layered structure showing a variable resistance characteristic with a combination of two or more layers. However, other implementations are also possible. For example, each of the memory cells 120 may include a memory layer capable of storing data in a way different from that of the above-described variable resistance layer 127.

In the implementation shown in FIG. 4A, each of the memory cells 120 includes the lower electrode layer 121, the selection element layer 123, the middle electrode layer 125, the variable resistance layer 127, and the upper electrode layer 129. However, implementations are not limited thereto, and the memory cell 120 may have any of various structures. In some implementations, one or more of the lower electrode layers 121, the middle electrode layer 125, and the upper electrode layer 129 may be omitted. In some implementations, the stacked order of the selection element layer 123 and the variable resistance layer 127 may be reversed with respect to the orientation of FIG. 4A, such that the selection element layer 123 may be disposed over the variable resistance layer 127. In some implementations, in addition to the element layers 121, 123, 125, 127, and 129 shown in FIG. 4A, the memory cell 120 may further include one or more layers (not shown) for enhancing characteristics of the memory cell 120, improving fabricating processes, or both.

Two neighboring memory cells of the plurality of memory cells 120 may be spaced apart from each other at a given interval, and trenches may be present between the plurality of memory cells 120. In an implementation, the given interval has a predetermined value, and a trench between two neighboring memory cells 120 may have a height to width ratio (or an aspect ratio) that is in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to a top surface of the substrate 100. In some implementations, neighboring trenches may be spaced apart from each other by substantially the same distance. For example, two neighboring trenches in a first direction (e.g., the first direction of FIG. 3) may be spaced apart from each other by substantially the same distance as two neighboring trenches in a second direction (e.g., the second direction of FIG. 4). In some implementations, distances between two neighboring trenches may vary.

Referring to FIG. 4B, an interlayer dielectric layer 140 may be formed over the structure illustrated in FIG. 4B. The interlayer dielectric layer 140 may include one of various insulating materials such as a silicon oxide, a silicon nitride, a silicon oxynitride, and the like. Moreover, the interlayer dielectric layer 140 may be formed along a lower profile, i.e., a profile of the structure illustrated in FIG. 4A. For example, the interlayer dielectric layer 140 is formed over exposed portions of the first lines 110, sidewalls of the memory cells 120, and upper surfaces and sidewalls of the hard mask patterns 130.

Referring to FIG. 4C, a planarization process may be performed on the interlayer dielectric layer 140 until the upper electrode layer 129 is exposed. The planarization process may be performed by a chemical mechanical polishing (CMP) process, an etch process, a cleaning process, or any suitable planarization process. Since the planarization process is performed until upper surfaces of the upper electrode layers 129 of the memory cells 120 are exposed, the hard mask patterns 130 may be removed by the planarization process.

Referring to FIG. 4D, a plurality of second lines 150 may be formed over the memory cells 120 and the interlayer dielectric layer 140. The plurality of second lines 150 may be respectively coupled to upper surfaces of the memory cells 120. Each of the plurality of second lines 150 extends in the second direction crossing the first direction. For example, the second direction may be perpendicular to the line A-A′ of FIG. 3. Each of the second lines 150 may have a single-layer structure or a multi-layer structure, and include a conductive material such as a metal, a metal nitride, or the like. The second lines 150 may be formed by depositing a conductive material and patterning a deposited conductive material layer. Spaces between the second lines 150 may be filled with an insulating material (not shown).

Through the processes described above, the semiconductor memory shown in FIG. 4D may be fabricated.

In the implementation shown in FIG. 4D, the semiconductor memory may include the memory cells 120 disposed in the intersection regions of the first lines 110 each extending in the first direction and the second lines 150 each extending in the second direction. In an implementation, the variable resistance layer 127 of the memory cells 120 may be formed by a sputtering process using a sputtering target. In an implementation, the selection element layer 123 may include the OTS material including the chalcogenide material which is formed by the PVD process using the shield structure 10 or structure 10′ in accordance with the above-mentioned implementations.

The memory cells 120 may store data having different values according to a voltage or current applied thereto through the first lines 110 and the second lines 150. In particular, when each of the memory cells 120 includes a variable resistance element, each of the memory cells 120 may store data determined by the variable resistance element switching between different resistance states.

One or more of the first lines 110 each may function as one of a word line and a bit line and one or more of the second lines 150 each may function as the other one of the word line and the bit line.

In the semiconductor memory of FIG. 4D, since the element layer 123 may be formed by the PVD process using the chamber shield structure in accordance with the above-mentioned implementations, the total capacitance can be reduced, thereby effectively decreasing the burn-in time for stabilizing the capacitance in the chamber.

In the implementations shown in FIGS. 3 to 4D, the semiconductor memory having a single-layer cross-point structure has been described. However, in another implementation, a semiconductor memory may have a multi-layer cross-point structure in which two or more cross-point structures may be stacked in a third direction perpendicular to the first and second directions. Each of the two or more cross-point structures may include first lines 110, second lines 150, and memory cells 120 located at respective intersections of the first lines 110 and the second lines 150.

Only a few implementations and examples are described above. Accordingly, other implementations, enhancements, and variations can be made based on what is described and illustrated in this patent document.

What is claimed is:

1. A physical vapor deposition (PVD) chamber shield structure comprising:
a shield configured to surround a space between a sputtering target and a substrate that are disposed in a PVD chamber body, the shield having a hollow shape with an inner surface and an outer surface; and
a coating layer formed over the inner surface of the shield,
wherein the coating layer has a dielectric constant not greater than that of a material deposited over the substrate during a PVD process.

2. The PVD chamber shield structure of claim 1, wherein the coating layer includes one or more of GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds, and YSZ (Yttria-stabilized Zirconia).

3. The PVD chamber shield structure of claim 1, wherein the coating layer has the dielectric constant less than 7.

4. The PVD chamber shield structure of claim 1, wherein a capacitance of the coating layer and a total capacitance in a PVD chamber are decreased compared to those when the coating layer includes a metal or a ceramic.

5. The PVD chamber shield structure of claim 1, wherein the material deposited over the substrate includes a chalcogenide material.

6. The PVD chamber shield structure of claim 1, wherein the shield includes a metal, a ceramic, or a combination thereof.

7. A PVD chamber shield structure comprising:
a shield configured to surround a space between a sputtering target and a substrate that are disposed in a PVD chamber body, the shield having a hollow shape with an inner surface and an outer surface; and
a coating layer formed over the inner surface of the shield,
wherein the coating layer has a porosity greater than 0 vol % and less than 100 vol %.

8. The PVD chamber shield structure of claim 7, wherein the coating layer includes one or more of GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds, and YSZ (Yttria-stabilized Zirconia).

9. The PVD chamber shield structure of claim 7, wherein the porosity of the coating layer is set not greater than 22 vol %.

10. The PVD chamber shield structure of claim 7, wherein a capacitance of the coating layer and a total capacitance in a PVD chamber are decreased compared to those when the coating layer is non-porous.

11. The PVD chamber shield structure of claim 7, wherein a material deposited over the substrate during a PVD process includes a chalcogenide material.

12. The PVD chamber shield structure of claim 7, wherein the shield includes a metal, a ceramic, or a combination thereof.

13. A PVD chamber shield structure comprising:
a shield configured to surround a space between a sputtering target and a substrate that are disposed in a PVD chamber body, the shield having a hollow shape with an inner surface and an outer surface; and
a coating layer formed over the inner surface of the shield,
wherein the coating layer has a thickness greater than 150 μm and less than a given upper limit, the upper limit being set to prevent an occurrence of peeling of a material deposited over the coating layer.

14. The PVD chamber shield structure of claim 13, wherein the coating layer includes one or more of GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds, and YSZ (Yttria-stabilized Zirconia).

15. The PVD chamber shield structure of claim 13, wherein the upper limit of the thickness of the coating layer is 1 mm.

16. The PVD chamber shield structure of claim 13, wherein a capacitance of the coating layer and a total capacitance in a PVD chamber are decreased compared to those when the coating layer has a thickness not greater than 150 μm.

17. The PVD chamber shield structure of claim 13, wherein a material deposited over the substrate includes a chalcogenide material.

18. The PVD chamber shield structure of claim 13, wherein the shield includes a metal, a ceramic, or a combination thereof.

19. A PVD chamber shield structure comprising:
a shield configured to surround a space between a sputtering target and a substrate that are disposed in a PVD chamber body, the shield having a hollow shape with an inner surface and an outer surface,
wherein a material deposited over the substrate during a PVD process is deposited over the inner surface of the shield, and
wherein the shield has a dielectric constant not greater than that of the material deposited over the substrate.

20. The PVD chamber shield structure of claim 19, wherein the shield includes one or more of GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds, and YSZ (Yttria-stabilized Zirconia).

21. The PVD chamber shield structure of claim 19, wherein the shield has the dielectric constant less than 7.

22. The PVD chamber shield structure of claim 19, wherein a capacitance of the shield and a total capacitance in a PVD chamber are decreased compared to those when the shield includes a metal or a ceramic.

23. The PVD chamber shield structure of claim 19, wherein the material deposited over the substrate includes a chalcogenide material.

24. A PVD chamber shield structure comprising:
a shield configured to surround a space between a sputtering target and a substrate that are disposed in a PVD chamber body, the shield having a hollow shape with an inner surface and an outer surface,
wherein a material deposited over the substrate during a PVD process is deposited over the inner surface of the shield, and
wherein the shield has a porosity greater than 0 vol % and less than 100 vol %.

25. The PVD chamber shield structure of claim 24, wherein the shield includes one or more of GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds, and YSZ (Yttria-stabilized Zirconia).

26. The PVD chamber shield structure of claim 24, wherein the porosity of the shield is set not greater than 22 vol %.

27. The PVD chamber shield structure of claim 24, wherein a capacitance of the shield and a total capacitance in a PVD chamber are decreased compared to those when the shield is non-porous.

28. The PVD chamber shield structure of claim 24, wherein the material deposited over the substrate includes a chalcogenide material.

29. A PVD chamber shield structure comprising:
a shield configured to surround a space between a sputtering target and a substrate that are disposed in a PVD chamber body, the shield having a hollow shape with an inner surface and an outer surface,
wherein a material deposited over the substrate during a PVD process is deposited over the inner surface of the shield, and
wherein the shield has a thickness greater than 150 μm and less than a given upper limit, the upper limit being set to prevent an occurrence of peeling of the material deposited over the shield.

30. The PVD chamber shield structure of claim 29, wherein the shield includes one or more of GeₓAs_{y}Te_{(1-x-y)}, GeₓAs_{y}Se_{(1-x-y)}, GeₓAs_{y}S_{(1-x-y)} (wherein, 0<x+y<1), Y₂O₃, YAG (Yttrium Aluminum Garnet), YAP (Yttrium Aluminum Perovskite), Y—Al—O-based compounds, Y—F-based compounds, Y—Cl-based compounds, Y—O—F-based compounds, Y—O—Cl-based compounds, Be—O-based compounds, Be—F-based compounds, Be—O—Cl-based compounds, and YSZ (Yttria-stabilized Zirconia).

31. The PVD chamber shield structure of claim 29, wherein the upper limit of the thickness of the shield is 1 mm.

32. The PVD chamber shield structure of claim 29, wherein a capacitance of the shield and a total capacitance in a PVD chamber are decreased compared to those when the shield has a thickness not greater than 150 μm.

33. The PVD chamber shield structure of claim 29, wherein the material deposited over the substrate includes a chalcogenide material.
